(19) United States
(12) Patent Application Publication
(10) Pub. No.: US 2025/0255071 A1
(43) Pub. Date: Aug. 7, 2025

(54) DISPLAY DEVICE

(71) Applicant: Innolux Corporation, Miaoli County (TW)

(72) Inventors: Chang-Chiang Cheng, Miaoli County (TW); Yu-Wei Tu, Miaoli County (TW); Chia-Hao Tsai, Miaoli County (TW); Yung-Hsun Wu, Miaoli County (TW)

(73) Assignee: Innolux Corporation, Miaoli County (TW)

(21) Appl. No.: 19/023,235

(22) Filed: Jan. 15, 2025

Related U.S. Application Data
(60) Provisional application No. 63/550,604, filed on Feb. 7, 2024.

(30) Foreign Application Priority Data
Nov. 1, 2024 (CN) 202411553132.7

(51) Int. Cl. H10H 29/49

(52) U.S. Cl. CPC H10H 29/49

(57) ABSTRACT

A display device includes a first pixel, a second pixel, and a backup bonding portion. The first pixel includes a first sub-pixel and a second sub-pixel corresponding to two first bonding portions. The second pixel includes a third sub-pixel and a fourth sub-pixel corresponding to two second bonding portions. Each of the two first bonding portions and two second bonding portions includes a first electrode and a second electrode. The backup bonding portion is proximate to the first and second pixels and electrically connected to an extension portion. The backup bonding portion includes a first electrode and a second electrode. The first electrode of one first bonding portion is electrically connected to a first metal pattern. The first electrode of one second bonding portion is electrically connected to a second metal pattern. The extension portion overlaps at least one of the first metal pattern and the second metal pattern.

### CROSS-REFERENCE TO RELATED APPLICATION

This application claims the priority benefits of U.S. provisional application Ser. No. 63/550,604, filed on Feb. 7, 2024, and China application serial no. 202411553132.7, filed on Nov. 1, 2024. The entirety of each of the above-mentioned patent applications is hereby incorporated by reference herein and made a part of this specification.

### BACKGROUND

### Technical Field

This disclosure relates to an electronic device, and in particular to a display device.

### Description of Related Art

With the advantages of low power consumption, high brightness, and fast response rate, Light-emitting diodes are suitable for use in display devices. When light-emitting diodes are used in a display device, the light-emitting diodes are batch bonded to the corresponding pixel layout. Sometimes it is not possible to ensure that all the light-emitting diodes are in good condition. As a result, display devices that use light-emitting diodes to realize picture displays often require the reservation of patch space.

### SUMMARY

The disclosure provides a display device with a patchable structure.

The display device of the disclosure includes a first pixel, a second pixel, and at least one backup bonding portion. The first pixel includes a first sub-pixel and a second sub-pixel, and the first sub-pixel and the second sub-pixel are disposed corresponding to two first bonding portion. Each of the two first bonding portions includes a first electrode and a second electrode. The second pixel includes a third sub-pixel and a fourth sub-pixel, and the third sub-pixel and the fourth sub-pixel are disposed corresponding to two second bonding portion. Each of the two second bonding portions includes a first electrode and a second electrode. The backup bonding portion is adjacent to the first pixel and the second pixel, and is electrically connected to an extension portion. The backup bonding portion includes a first electrode and a second electrode. The first electrode of one of the two first bonding portions is electrically connected to a first metal pattern, and the first electrode of one of the two second bonding portions is electrically connected to a second metal pattern. The extension portion is disposed on the first metal pattern and the second metal pattern, and overlaps at least one of the first metal pattern and the second metal pattern.

According to the display device according to the embodiment of the disclosure, the backup bonding portion is used for patch for the sub-pixel, so that the display device can be patched when necessary to improve the yield rate of the display device. After patching, the patched structure provided by the backup bonding portion can be used as a sub-pixel for display. If not patched, the structure of the backup bonding portion has no display function. Multiple sub-pixels in the display device can share the backup bonding portion, so a sufficient number and density of sub-pixels can still be disposed in the display device. Overall, the display device can still achieve high resolution, high pixel density, high brightness and other requirements while having a backup bonding portion as a patch structure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic diagram of a display device according to an embodiment of the disclosure.

FIG. 2 is a schematic layout diagram of a sub-pixel and a backup bonding portion of a display device according to an embodiment of the disclosure.

FIG. 3 is a schematic layout diagram of a sub-pixel and a backup bonding portion of a display device according to an embodiment of the disclosure.

FIG. 4 is a partial schematic diagram of a display device according to an embodiment of the disclosure.

FIG. 5 is a schematic cross-sectional diagram of a display device of FIG. 4 along a line I-I′ in some embodiments.

FIG. 6 is a schematic diagram of a display device in FIG. 5 after patch.

FIG. 7 is a schematic diagram of a partial component layout of a display device according to some embodiments of the disclosure.

FIG. 8 is a schematic diagram of a partial component layout of a display device according to some embodiments of the disclosure.

FIG. 9 is a schematic diagram of a partial component layout of a display device according to some embodiments of the disclosure.

### DESCRIPTION OF THE EMBODIMENTS

Reference will now be made in detail to the exemplary embodiments of the disclosure, examples of which are illustrated in the accompanying drawings. Whenever possible, the same reference numerals are used in the drawings and descriptions to refer to the same or similar parts.

The ordinal numbers used in the specification and claims, such as “first” and “second”, are used to modify elements, do not in themselves imply or represent any prior ordinal sequence for such element(s), nor do they indicate any order between one element and another, or any order in the manufacturing process. The use of these ordinal numbers is solely for the purpose of clearly distinguishing between elements bearing the same nomenclature. Claims and specification may not use identical terminology. Accordingly, the first component described in the specification may be referred to as the second component in the claims.

Certain words are used throughout the specification and claims to refer to specific elements. Those skilled in the art understand that electronic device manufacturers may refer to the same element by different names. This article is not intended to differentiate between elements that have the same function but have different names. In the following specification and claims, words such as “comprise”, “include”, and “have” are open-ended words, so they should be interpreted as meaning “including but not limited to . . . ”. Therefore, when the terms “comprise”, “include”, and/or “have” are used in the description of the disclosure, they specify the presence of the corresponding features, regions, steps, operations, and/or components, but do not exclude the presence of one or more of corresponding features, regions, steps, operations and/or components.

In this disclosure, when one structure (or layer, component, substrate) is described as being “on” or “above” another structure (or layer, component, substrate), it may refer to instances where the two structures are adjacent and directly connected, or it may refer to instances where the two structures are adjacent but not directly connected. In the latter case, there is at least one intervening structure (or intervening layer, intervening component, intervening substrate, intervening spacing) between the two structures. The lower surface of one structure is adjacent to or directly connected to the upper surface of the intervening structure, while the upper surface of the other structure is adjacent to or directly connected to the lower surface of the intervening structure. The intervening structure may be composed of a single layer or multiple layers, and may be a physical or non-physical structure, without limitation. In this disclosure, when a structure is described as being “on” another structure, it may refer to the structure being “directly” on the other structure, or “indirectly” on the other structure, meaning that there may be at least one intervening structure between the structure and the other structure.

It should be understood that when a component or layer is described as “connected to” another component or layer, it may be directly connected to the another component or layer, or there may be intervening components or layers present. When a component is described as “directly connected to” another component or layer, there are no intervening components or layers present. Furthermore, when a component is described as “coupled to” another component (or a variant thereof), it can be directly connected to the another component, or indirectly connected (e.g., electrically connected) to the another component through one or more intervening components.

The electrical connection or coupling described in this disclosure can refer to direct connection or indirect connection. In the case of direct connection, the end points of the elements on two circuits are directly connected or connected to each other with a conductor line segment, and in the case of indirect connection, there are switches, diodes, capacitors, inductors, resistors, other suitable elements, or combinations of the above elements between the end points of the elements on the two circuits, but are not limited thereto.

In the disclosure, the thickness, length, and width can be measured using an optical microscope, and the thickness can be measured using cross-sectional images in an electron microscope, but is not limited thereto.

In the disclosure, various embodiments described below may be mixed and matched without departing from the spirit and scope of the disclosure. For example, some features of one embodiment may be combined with some features of another embodiment to form another embodiment.

The display device disclosed in this disclosure can be any type of display device, such as color display device, monochrome display device, transparent display device, double-sided display device, virtual reality display device, augmented reality display device, 3D display device, splicing display device, flexible display device, foldable display device, stretchable display device, rollable display device, but not limited thereto. In some embodiments, the display device may include a self-illuminating display device and a non-self-illuminating display device. The self-luminous display device may include a light-emitting diode, a light conversion layer or other suitable materials, or a combination of the above, but is not limited thereto. The light-emitting diode may include, for example, an organic light-emitting diode (OLED), a sub-millimeter light-emitting diode (mini LED), a micro-light-emitting diode (micro LED), or a quantum dot light-emitting diode (quantum dot LED, which can include QLED, QDLED), but is not limited thereto. The light conversion layer may include wavelength conversion materials and/or filter materials. The light conversion layer may include, for example, fluorescence, phosphor, Quantum Dot (QD), other suitable materials, or a combination of the above, but is not limited thereto. The non-self-luminous display devices may include liquid crystal display devices, but is not limited thereto. In addition, the appearance of the display device may be, for example, a rectangle, a circle, a polygon, a shape with curved edges, a curved surface, or other suitable shapes. The display device can have peripheral systems such as drive system, control system, light source system, shelf system. The display device may include an electronic unit, where the electronic unit may include passive elements and active elements, such as capacitors, resistors, inductors, diodes, transistors, sensors. It should be noted that the display device of the disclosure can be various combinations of the above devices, but is not limited thereto.

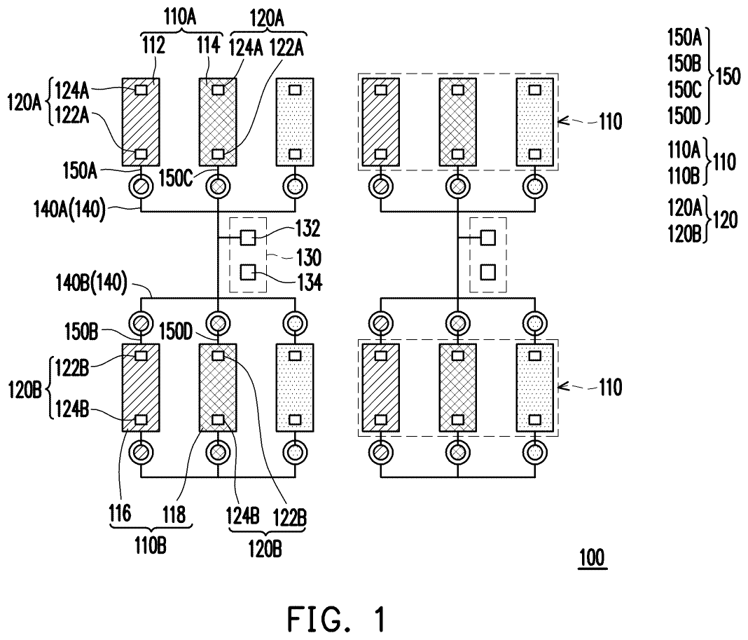

FIG. 1 is a schematic diagram of a display device according to an embodiment of the disclosure A display device 100 in FIG. 1 includes multiple pixels 110, and the pixels 110 are arranged in an array. For convenience of explanation, two of the pixels 110 are described in detail below, namely a first pixel 110A and a second pixel 110B. The description of the first pixel 110A and the second pixel 110B can also be applied to other pixels 110. The first pixel 110A includes multiple sub-pixels, and the second pixel 110B includes multiple sub-pixels. FIG. 1 only schematically presents the settings of the pixels 110 and the sub-pixels. In fact, the orientation direction and arrangement rules of the sub-pixels can be adjusted according to different design requirements. In some embodiments, at least part of the sub-pixels may be circular, square, or other shapes. In some embodiments, at least part of the sub-pixels may be oriented with the long axes disposed in one direction and the long axes of other sub-pixels disposed in another direction. In some embodiments, the sub-pixels can be arranged in an array, have a staggered arrangement, or other arrangements. In some embodiments, the first pixel 110A and the second pixel 110B may include three sub-pixels or more sub-pixels respectively. For example, the first pixel 110A and the second pixel 110B include a red sub-pixel, a blue sub-pixel, and a blue sub-pixel respectively. In the disclosure, the pixel and/or sub-pixel can be determined by, for example, the last display light displayed by the display device, but is not limited thereto. For the convenience of explanation, the following description uses two sub-pixels of the first pixel 110A and two sub-pixels of the second pixel 110B to illustrate, but the number of sub-pixels of an individual pixel 110 is not limited thereto.

The first pixel 110A includes a first sub-pixel 112 and a second sub-pixel 114, and the second pixel 110B includes a third sub-pixel 116 and a fourth sub-pixel 118. The second sub-pixel 114 may be, for example, of a different color than the first sub-pixel 112, and the fourth sub-pixel 118 may be, for example, of a different color than the third sub-pixel 116. In some embodiments, individual sub-pixel such as the first sub-pixel 112, the second sub-pixel 114, the third sub-pixel 116, and the fourth sub-pixel 118 may include light-emitting units, such as light-emitting diodes or micro-light-emitting diodes, sub-millimeter light-emitting diodes, and organic light-emitting diodes. Each sub-pixel can be controlled through each sub-pixel circuit (e.g., switching element/transistor). In some embodiments, sub-pixels of different colors can be implemented through light-emitting units of different colors. For example, red sub-pixel, blue sub-pixel, and green sub-pixel can be implemented by red light-emitting unit, blue light-emitting unit, and green light-emitting unit. In some embodiments, sub-pixels of different colors can be implemented through light-emitting units of the same color with different filter materials and/or wavelength conversion materials (such as quantum dots). For example, red sub-pixel, blue sub-pixel, and green sub-pixel can be implemented through the filter materials and/or wavelength conversion materials (such as quantum dots) corresponding to each of the blue light-emitting unit, red sub-pixel, blue sub-pixel, and green sub-pixel. Sub-pixels of different colors can provide display lights of different colors (such as red, green, and blue). Therefore, the first pixel 110A and the second pixel 110B can display multiple colors through the brightness adjustment of different sub-pixels. In some embodiments, according to different types of display devices or display requirements, multiple pixels or multiple sub-pixels can be light-emitting units of the same color to provide display light of the same color but different brightness or angle. In some embodiments, the number of sub-pixels of different colors in the same pixel 110 may be different. For example, the number of red sub-pixels may be greater than the number of at least one of blue sub-pixels and green sub-pixels. In some embodiments, the light-emitting areas of sub-pixels of different colors may be different. For example, the light-emitting area of the red sub-pixel may be larger than the light-emitting area of at least one of the blue sub-pixel and the green sub-pixel. In some embodiments, the shapes of sub-pixels of different colors can be different.

The display device 100 also includes multiple bonding portions 120 corresponding to individual sub-pixels. In some embodiments, individual pixel 110 may include the light-emitting units and circuit layers. The bonding portion 120 may be part of the circuit layer of the individual pixel 110, and the circuit layer may be used to provide driving signals and power to the light-emitting units. For convenience of explanation, the bonding portion 120 corresponding to the first pixel 110A is hereinafter referred to as a first bonding portion 120A, and the bonding portion 120 corresponding to the second pixel 110B is hereinafter referred to as a second bonding portion 120B. In addition, the first sub-pixel 112 and the second sub-pixel 114 are disposed corresponding to two first bonding portions 120A, and the third sub-pixel 116 and the fourth sub-pixel 118 are disposed corresponding to two second bonding portions 120B.

The display device 100 also includes a backup bonding portion 130. The backup bonding portion 130 is adjacent to the first pixel 110A and the second pixel 110B, and is electrically connected to an extension portion 140. Here, FIG. 1 is only used to illustrate the connection relationship of individual components, and is not used to limit the arrangement position and structural shape of individual components. In some embodiments, the backup bonding portion 130 may be disposed between the first pixel 110A and the second pixel 110B, but the disclosure is not limited thereto. In some embodiments, the backup bonding portion 130 can be arranged in a specified arrangement with the sub-pixels, or the arrangement position of the backup bonding portion 130 can be different from the arrangement of the sub-pixels. Although this embodiment is illustrated by arranging one backup bonding portion 130 for two adjacent pixels 110, it is not limited thereto. In some implementations, two backup bonding portions 130 may be disposed corresponding to two adjacent pixels 110, or other numbers of the backup bonding portions 130.

The display device 100 also includes an extension portion 140, and the backup bonding portion 130 is electrically connected to the extension portion 140. The extension portion 140 may be disposed between the backup bonding portion 130 and the first pixel 110A and between the backup bonding portion 130 and the second pixel 110B. For convenience of explanation, the extension portion 140 may be divided into an extension portion 140A disposed between the backup bonding portion 130 and the first pixel 110A and an extension portion 140B disposed between the backup bonding portion 130 and the second pixel 110B. The extension portion 140A and the extension portion 140B are electrically connected and may be disposed at the same level, for example. In some embodiments, the extension portion 140A and the extension portion 140B may both be connected to a first electrode 132 of the backup bonding portion 130. In some embodiments, the extension portion 140A and the extension portion 140B may be composed of an integral continuous conductive pattern.

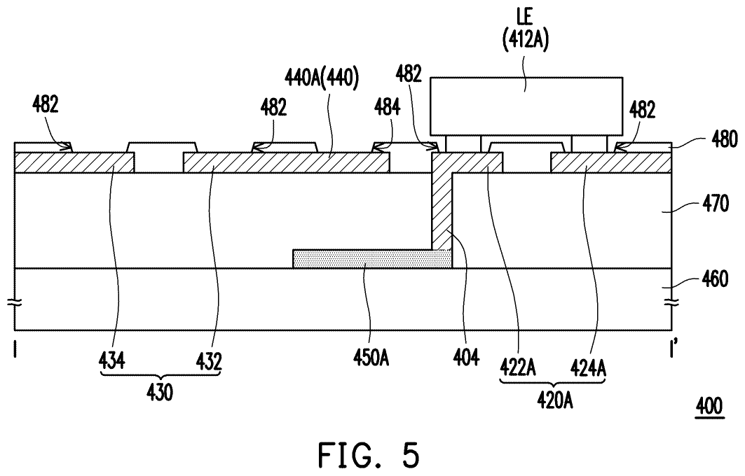

The display panel 100 also includes multiple metal patterns 150. Here, a first metal pattern 150A corresponding to the first pixel 110A and a second metal pattern 150B corresponding to the second pixel 110B are explained. One of the two first bonding portions 120A is electrically connected to the first metal pattern 150A, and one of the two second bonding portions 120B is electrically connected to the second metal pattern 150B. In addition, as shown in FIG. 5, the extension portion 140 may be disposed on the first metal pattern 150A and the second metal pattern 150B, and the extension portion 140 overlaps with at least one of the first metal pattern 150A and the second metal pattern 150B. For example, the extension portion 140A overlaps the first metal pattern 150A, and/or the extension portion 140B overlaps the second metal pattern 150B.

The bonding portion 120, the backup bonding portion 130, the extension portion 140, the first metal pattern 150A, and the second metal pattern 150B shown in FIG. 1 are all components made of conductive materials and can be used to achieve required electrical connections. In some embodiments, each of the two first bonding portions 120A includes a first electrode 122A and a second electrode 124A, and each of the two second bonding portions 120B includes a first electrode 122B and a second electrode 124B. In addition, the light-emitting unit of the first sub-pixel 112 may be bonded to the first electrode 122A and the second electrode 124A of the corresponding first bonding portion 120A, and the light-emitting unit of the second sub-pixel 114 may be bonded to the first electrode 122A and the second electrode 124A of the corresponding first bonding portion 120A. Similarly, the light-emitting unit of the third sub-pixel 116 can be bonded to the first electrode 122B and the second electrode 124B of the corresponding second bonding portion 120B, and the light-emitting unit of the fourth sub-pixel 118 can be bonded to the first electrode 122B and the second electrode 124B of the corresponding second bonding portion 120B.

In some embodiments, the light-emitting unit bonded to the individual bonding portion 120 may be a light-emitting diode, and the first electrode and the second electrode of the individual bonding portion 120 may be electrodes of different polarities respectively. For example, the first electrode 122A in the individual first bonding portion 120A can be a P electrode and the second electrode 124A in the individual first bonding portion 120A can be an N electrode. Similarly, the first electrode 122B in the individual second bonding portion 120B can be a P electrode and the second electrode 124B in the individual second bonding portion 120B can be an N electrode. In some embodiments, the individual N electrode may be connected to the same potential. In other words, the second electrode 124A in the individual first bonding portion 120A and the second electrode 124B in the individual second bonding portion 120B may be connected to the same potential and/or be electrically connected to each other, but are not limited thereto.

In some embodiments, each backup bonding portion 130 may include a first electrode 132 and a second electrode 134. Similar to the design of the bonding portion 120, the first electrode 132 and the second electrode 134 of each backup bonding portion 130 may be electrodes of different polarities. The first electrode 132 of each backup bonding portion 130 is selectively electrically connected to the first electrode 122A in one of the first bonding portions 120A or the first electrode 122B in one of the second bonding portions 120B, and provides the same polarity as the connected electrode to achieve the patch function. At the same time, the corresponding second electrode 134 provides the other polarity. In some embodiments, the first electrode 132 of individual backup bonding portion 130 may be electrically connected to the corresponding bonding portion 120 through the corresponding extension portion 140 and metal pattern 150. In some embodiments, the second electrode 134 of individual backup bonding portion 130 may be electrically connected to a second electrode (e.g., 124A, 124B) of the bonding portion 120. In some embodiments, the second electrode 134 of individual backup bonding portion 130 may be physically connected to the second electrode (e.g., 124A, 124B) of the bonding portion 120.

In FIG. 1, the first electrode 122A of one of the two first bonding portions 120A may be electrically connected to first metal pattern 150A. Similarly, the first electrode 122B of one of the two second bonding portions 120B is electrically connected to the second metal pattern 150B. For example, the first metal pattern 150A may be disposed between the first sub-pixel 112 and the extension portion 140A, and the first electrode 122A corresponding to the first bonding portion 120A of the first sub-pixel 112 may be electrically connected to the first metal pattern 150A. Similarly, the second metal pattern 150B can be disposed between the third sub-pixel 116 and the extension portion 140B, and the first electrode 122B corresponding to the second bonding portion 120B of the third sub-pixel 116 can be electrically connected to the second metal pattern 150B. In some embodiments, the second electrode 124A corresponding to the first bonding portion 120A of the first sub-pixel 112 and the second electrode 124A corresponding to the first bonding portion 120A of the second sub-pixel 114 may be connected to the same potential or be electrically connected to each other. Similarly, the second electrode 124B corresponding to the second bonding portion 120B of the third sub-pixel 116 and the second electrode 124B corresponding to the second bonding portion 120B of the fourth sub-pixel 118 may be connected to the same potential or be electrically connected to each other.

In FIG. 1, the display device 100 may further include another first metal pattern 150C and another second metal pattern 150D, for example. The first metal pattern 150C may be disposed between the second sub-pixel 114 and the extension portion 140A, and the first electrode 122A corresponding to the first bonding portion 120A of the second sub-pixel 114 may be electrically connected to the first metal pattern 150C. Similarly, the second metal pattern 150D may be disposed between the fourth sub-pixel 118 and the extension portion 140B, and the first electrode 122B corresponding to the second bonding portion 120B of the fourth sub-pixel 118 may be electrically connected to the second metal pattern 150D. In some embodiments, other sub-pixels of the first pixel 110A and the second pixel 110B can also be configured with corresponding metal patterns 150. In some embodiments, the backup bonding portion 130 can be disposed corresponding to the first pixel 110A and the second pixel 110B through the extension portion 140 and the circuit layout of the metal pattern 150. When any sub-pixel of the first pixel 110A and the second pixel 110B needs to be patched, this can be accomplished by bonding an additional light-emitting unit (such as a light-emitting diode) to the backup bonding portion 130 and electrically connecting the backup bonding portion 130 to the corresponding bonding portion 120.

For example, when the light-emitting unit of the first sub-pixel 112 in the first pixel 110A is determined to be unable to operate normally, the patch step may include: bonding additional light-emitting units (such as light-emitting diodes) to the backup bonding portion 130; electrically connecting the backup bonding portion 130 to the first bonding portion 120A of the first sub-pixel 112 through the extension portion 140A and the first metal pattern 150A; and electrically disconnecting the backup bonding portion 130 from other bonding portions 120. At this time, the backup bonding portion 130 and the light-emitting unit bonded thereto can be used to replace the first sub-pixel 112.

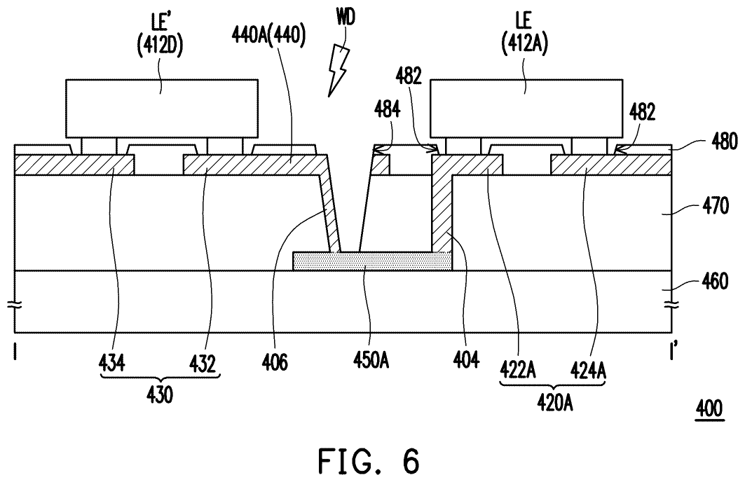

In some embodiments, the extension portion 140 and all metal patterns 150 overlap each other but are not connected before patching, as shown in FIG. 5. At this time, the method for electrically connecting the backup bonding portion 130 to the first bonding portion 120A of the first sub-pixel 112 through the first metal pattern 150A of the extension portion 140A includes welding together the extension portion 140A and the first metal pattern 150A that are overlapped with each other (such as FIG. 6), and the method for electrically disconnecting the backup bonding portion 130 from other bonding portions 120 includes maintaining the extension portion 140A/140B and other metal patterns other than the first metal pattern 150A in the structure before patch (for example, overlapping each other but not connected). In other words, after the first sub-pixel 112 of the first pixel 110A is patched, the extension portion 140 overlaps with one of the first metal pattern 150A and the second metal pattern 150B (for example, the second metal pattern 150B), and the extension portion 140 connects to one of the first metal pattern 150A and the second metal pattern 150B (for example, the first metal pattern 150A).

In some embodiments, the extension portion 140 and all metal patterns 150 are connected to each other before patching. At this time, the method for electrically connecting the backup bonding portion 130 to the first bonding portion 120A of the first sub-pixel 112 through the extension portion 140A and the first metal pattern 150A includes maintaining the extension portion 140A and the first metal pattern 150A in the structure before patch (i.e., connected to each other), and the method for electrically disconnecting the backup bonding portion 130 from other bonding portions 120 includes using laser cutting or a similar method to disconnect the extension portion 140A/140B from other metal patterns other than the first metal pattern 150A. In this way, the extension portion 140 is connected to the corresponding first metal pattern 150A to establish the required electrical connection relationship.

Similarly, when the third sub-pixel 116 of the second pixel 110B needs to be patched, additional light-emitting units (such as light-emitting diodes) can be bonded to the backup bonding portion 130. At the same time, the backup bonding portion 130 is electrically connected to the second bonding portion 120B of the third sub-pixel 116 through the extension portion 140B and the second metal pattern 150B, and the backup bonding portion 130 is electrically disconnected from other bonding portions 120, so that the sub-pixel bonded to the backup bonding portion 130 can be allowed to replace the third sub-pixel 116. In some embodiments, after the third sub-pixel 116 of the second pixel 110B is patched, the extension portion 140 overlaps one of the first metal pattern 150A and the second metal pattern 150B (e.g., the first metal pattern 150A), and the extension portion 140 connects to one of the first metal pattern 150A and the second metal pattern 150B (e.g., the second metal pattern 150B).

In this embodiment, multiple sub-pixels in the first pixel 110A and the second pixel 110B may share one backup bonding portion 130. For example, when the first pixel 110A has N sub-pixels and the second pixel 110B has M sub-pixels, N+M sub-pixels may share one backup bonding portion 130. However, this disclosure is not limited thereto. In other embodiments, the extension portion 140B may be omitted and the backup bonding portion 130 may only be used as a patch structure shared by multiple sub-pixels in the first pixel 110A. In this way, the number of the backup bonding portion 130 is still less than the number of the sub-pixels. The display device 100 does not need to excessively sacrifice the configuration area of the sub-pixel in order to set up a large number of patch structures, which helps to increase the display aperture ratio. In other words, while the display device 100 has the backup bonding portion 130 for patch purposes, it can also have an ideal pixel density to achieve high resolution, high brightness, and other requirements.

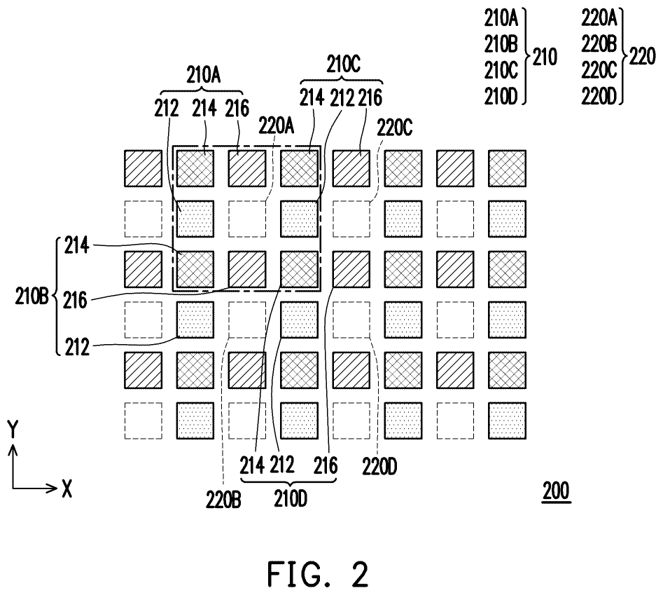

FIG. 2 is a schematic layout diagram of a sub-pixel and a backup bonding portion of a display device according to an embodiment of the disclosure. A display device 200 includes multiple pixels 210 and multiple patch structures 220. In this embodiment, each pixel 210 includes three sub-pixels 212, 214 and 216, but is not limited thereto. The sub-pixels 212, 214, and 216 and the patch structure 220 may be arranged in an array in a first direction X and a second direction Y, where the first direction X and the second direction Y are, for example, perpendicular to each other. At the same time, each pixel 210 can be disposed corresponding to one patch structure 220. Thus, the ratio of the number of the patch structure 220 to the number of the sub-pixels 212, 214, and 216 is approximately 1:3. In some embodiments, the display device 200 may include a light-emitting unit and a bonding portion (the bonding portion 120 as shown in FIG. 1) corresponding to each sub-pixel 212, 214, and 216, and the patch structure 220 may be implemented specifically by the backup bonding portion 130, the extension portion 140, and the metal pattern 150 as shown in FIG. 1.

For convenience of explanation, only part of the pixels 210A to 210D and part of the patch structures 220A to 220D are marked in FIG. 2. In this embodiment, the patch structure 220A is simultaneously adjacent to the sub-pixels 212, 214 and 216 of the pixel 210A, adjacent to the sub-pixels 214 and 216 of the pixel 210B, and adjacent to the sub-pixels 212 and 214 of the pixel 210C, and adjacent to the sub-pixel 214 of pixel 210D. Therefore, although the ratio of the number of the patch structure 220 to the number of the sub-pixels 212, 214 and 216 is 1:3, the configuration of a single patch structure 220 adjacent to eight sub-pixels makes it possible for each patch structure 220 to be a patch structure shared by eight sub-pixels, as shown in the dotted-link frame in FIG. 2. In addition, the sub-pixel 216 of the pixel 210B is adjacent to both the patch structure 220A and the patch structure 220B. When the sub-pixel 216 of the pixel 210B needs to be patched, it can be patched by one of the patch structure 220A and the patch structure 220B. Similarly, the sub-pixel 212 of the pixel 210C is adjacent to both the patch structure 220A and the patch structure 220C. Therefore, when the sub-pixel 212 of the pixel 210C needs to be patched, it can be patched by one of the patch structure 220A and the patch structure 220C. In this way, in the display device 200, in addition to each patch structure 220 providing for patching of the sub-pixels 212, 214, and 216, each sub-pixel 212, 214, and 216 may also be patched by one of two patch structures 220 when the sub-pixels 212, 214, and 216 need to be patched. Therefore, the display device 200 provides a flexible patching design. In addition, the smaller number of the patch structure 220C and the small configuration space required allow the sub-pixel layout density is not sacrificed and an ideal display aperture ratio can be achieved. In some embodiments, after the display device 200 is patched, at least one of the patch structures 220 may be provided with a light-emitting unit for patch, while the remaining patch structures 220 remain idle. At this time, the light-emitting units in the sub-pixels 212, 214 and 216 that were originally unable to work normally are also retained in the display device 200. Therefore, in the patched display device 200, the number of the light-emitting units may be greater than the total number available for the display sub-pixels 212, 214, and 216.

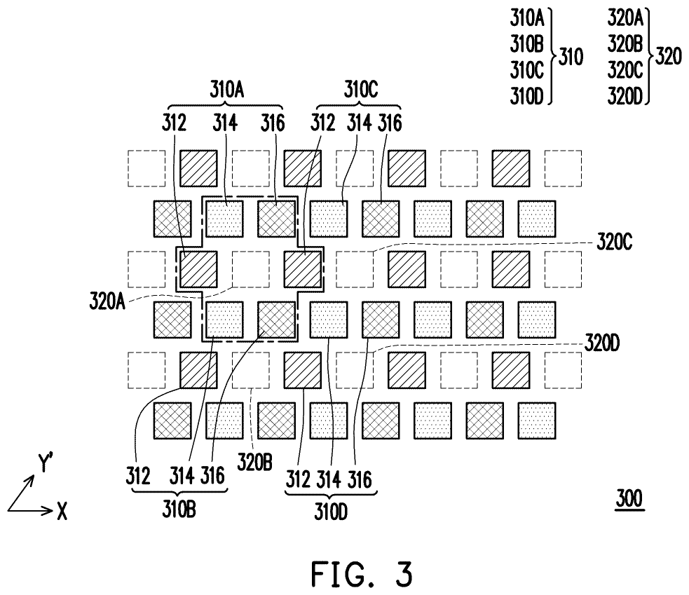

FIG. 3 is a schematic layout diagram of a sub-pixel and a backup bonding portion of a display device according to an embodiment of the disclosure. A display device 300 includes multiple pixels 310 and multiple patch structures 320. Each pixel 310 includes three sub-pixels 312, 314 and 316. Each patch structure 320 is disposed corresponding to one of the pixels 310. The sub-pixels 312, 314 and 316 and the patch structure 320 are arranged in an array in the first direction X and a second direction Y′, where the first direction X and the second direction Y′ intersect but are not perpendicular to each other. Thus, the ratio of the number of the patch structure 320 to the number of the sub-pixels 312, 314, and 316 is approximately 1:3. In some embodiments, each sub-pixel 312, 314, and 316 may include a light-emitting unit and a corresponding bonding portion (e.g., the bonding portion 120 as shown in FIG. 1), and the patch structure 320 may be specifically implemented by the backup bonding portion 130, the extension portion 140, and the metal pattern 150 as shown in FIG. 1.

For convenience of explanation, only part of pixels 310A to 310D and part of patch structures 320A to 320D are marked in FIG. 3. In this embodiment, the patch structure 320A is simultaneously adjacent to the sub-pixels 312, 314, and 316 of the pixel 310A, adjacent to the sub-pixels 314 and 316 of the pixel 310B, and adjacent to the sub-pixel 312 of the pixel 310C. Therefore, although the ratio of the number of the patch structure 320 to the number of the sub-pixels 312, 314, and 316 is approximately 1:3, a single patch structure 320 can provide patches for six sub-pixels 312, 314, and 316, as shown in the dotted-link frame in FIG. 3. In addition, the sub-pixels 314 and 316 of the pixel 310B are adjacent to both the patch structure 320A and the patch structure 320B. When the sub-pixels 314 and 316 of the pixel 310B need to be patched, they can be patched by one of the patch structure 320A and the patch structure 320B. Similarly, the sub-pixel 312 of the pixel 310C is adjacent to both patch structure 320A and the patch structure 320C. Therefore, when the sub-pixel 312 of the pixel 310C needs to be patched, it can be patched by one of the patch structure 320A and the patch structure 320C. In this way, in the display device 300, in addition to each patch structure 320 providing for patching of the sub-pixels 314, 314, and 316, each sub-pixel 312, 314, and 316 may also be patched by one of two patch structures 320 when the sub-pixels 312, 314, and 316 need to be patched.

The embodiments of FIG. 2 and FIG. 3 are both illustrated with three sub-pixels forming one pixel, and the three sub-pixels in the same pixel may optionally have different luminous colors, but the disclosure is not limited thereby. In some embodiments, each pixel may have more sub-pixels, and/or each pixel may include two or more sub-pixels of the same color. In addition, although the embodiments of FIG. 2 and FIG. 3 disclose that every three sub-pixels correspond to one patch structure to form an array arrangement, in some embodiments, every multiple sub-pixels may be disposed in such a way that every multiple sub-pixels corresponds to two or more patch structures.

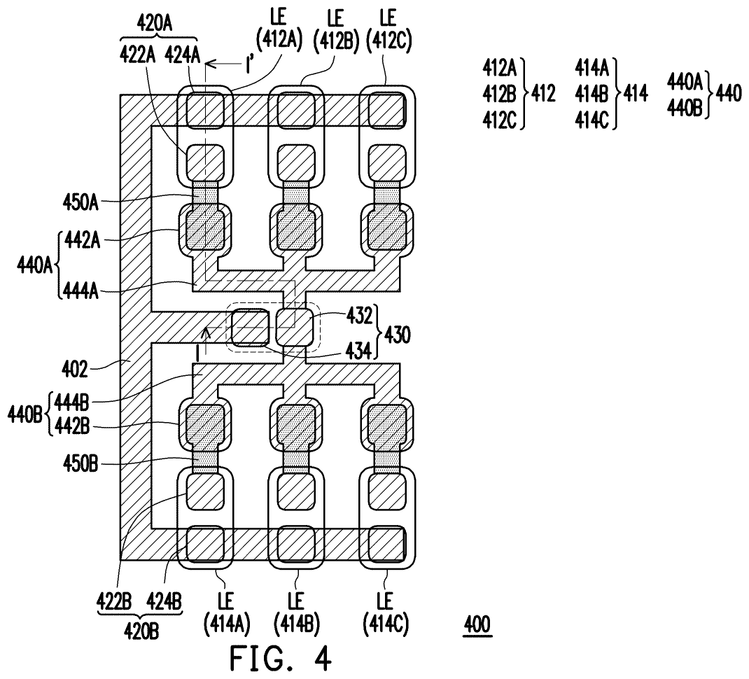

FIG. 4 is a partial schematic diagram of a display device according to an embodiment of the disclosure. A display device 400 includes multiple pixels, and FIG. 4 schematically shows two of them, namely a pixel 412 and a pixel 414. The pixel 412 includes a sub-pixel 412A, a sub-pixel 412B, and a sub-pixel 412C, and the sub-pixel 412A, the sub-pixel 412B, and the sub-pixel 412C may have different luminous colors. The pixel 414 includes a sub-pixel 414A, a sub-pixel 414B, and a sub-pixel 414C, and the sub-pixel 414A, sub-pixel 414B, and the sub-pixel 414C may have different luminous colors. In some embodiments, the arrangement relationship between the pixel 412 and the pixel 414 may be referred to the arrangement relationship between the first pixel 110A and the second pixel 110B in FIG. 1. For example, two of the sub-pixel 414A, the sub-pixel 414B, and the sub-pixel 414C can be understood as the first sub-pixel 112 and second sub-pixel 114 in the aforementioned embodiment, and two of the sub-pixel 414A, the sub-pixel 414B, and the sub-pixel 414C can be understood as the third sub-pixel 116 and the fourth sub-pixel 118 in the aforementioned embodiment. At the same time, the arrangement relationship of the first sub-pixel 112, the second sub-pixel 114, the third sub-pixel 116, and the fourth sub-pixel 118 described in FIG. 1 can also be applied to the display device 400.

The display device 400 also includes multiple first bonding portions 420A corresponding to individual sub-pixels 412A to 412C, and each first bonding portion 420A includes a first electrode 422A and a second electrode 424A. Individual sub-pixels 412A to 412C may further include light-emitting units LE bonded to the first electrode 422A and the second electrode 424A of the corresponding first bonding portion 420A. In some embodiments, the light-emitting units LE of the individual sub-pixels 412A to 412C are, for example, light-emitting diodes, and the first electrode 422A and the second electrode 424A of the individual first bonding portion 420A can be electrodes of different polarities (which can also be understood as pads).

Similarly, the display device 400 also includes multiple second bonding portions 420B corresponding to individual sub-pixels 414A to 414C, and each second bonding portion 420B includes a first electrode 422B and a second electrode 424B. Individual sub-pixels 414A to 414C also include the light-emitting units LE bonded to the first electrode 422B and the second electrode 424B of the corresponding second bonding portion 420B. In some embodiments, the light-emitting units LE are, for example, light-emitting diodes, and the first electrode 422A and the second electrode 424B of the each second bonding portion 420B can be electrodes of different polarities (which can also be understood as pads).

The display device 400 also includes at least a backup bonding portion 430 and an extension portion 440. The backup bonding portion 430 is adjacent to the pixel 412 and the pixel 414. The extension portion 440 includes an extension portion 440A disposed between the backup bonding portion 430 and the pixel 412 and an extension portion 440B disposed between the backup bonding portion 430 and the pixel 414. The extension portion 440A and the extension portion 440B are electrically connected and may be disposed at the same level, for example. In some embodiments, the extension portion 440A and the extension portion 440B may be composed of an integral continuous conductive pattern. The backup bonding portion 430 may include a first electrode 432 and a second electrode 434, and the first electrode 432 connects the extension portion 440A and the extension portion 440B. In some embodiments, the second electrode 424A corresponding to the first bonding portion 420A of the sub-pixels 412A to 412C, the second electrode 424B corresponding to the second bonding portion 420B of the sub-pixels 414A to 414C, and the second electrode 434 of the backup bonding portion 430 can be connected to the same potential and for example connected together through an electrode connection pattern 402.

The display device 400 may also include a first metal pattern 450A corresponding to individual sub-pixels 412A to 412C and a second metal pattern 450B corresponding to individual sub-pixels 414A to 414B. The number of the first metal pattern 450A can correspond to the sub-pixels 412A to 412C, and the number of the second metal pattern 450B can correspond to the sub-pixels 414A to 414B. In some embodiments, individual first metal pattern 450A can connect to the first electrode 422A of the corresponding first bonding portion 420A, and individual second metal pattern 450B can connect to the first electrode 422B of the corresponding second bonding portion 420B. For example, the first metal pattern 450A corresponding to the sub-pixel 412A may be connected to the first electrode 422A of the first bonding portion 420A corresponding to the sub-pixel 412A. Similarly, the second metal pattern 450B corresponding to the sub-pixel 414A may be connected to the first electrode 422B of the second bonding portion 420B corresponding to the sub-pixel 414A.

In this embodiment, the extension portion 440A includes multiple patch regions 442A overlapping individual first metal pattern 450A and a connection pattern 444A connecting the patch regions 442A to the backup bonding portion 430. That is, the connection pattern 444A extends between the patch region 442A and the first electrode 432 of the backup bonding portion 430. Similarly, the extension portion 440B includes multiple patch regions 442B overlapping the second metal pattern 450B and a connection pattern 444B, where the connection pattern 444B connects the patch regions 442B to the first electrode 432 of the backup bonding portion 430. In some embodiments, the first electrode 432 of the extension portion 440A, the extension portion 440B, and the backup bonding portion 430 may be a continuous and integrated conductor pattern, but is not limited thereto. Therefore, the entire extension portion 440 may overlap with both the first metal pattern 450A and the second metal pattern 450B. The layout design of the backup bonding portion 430 and the extension portion 440 in FIG. 4 can be regarded as an implementation of the backup bonding portion 130 and the extension portion 140 in FIG. 1, and the electrode connection pattern 402 of FIG. 4 can be applied to the display 100 of FIG. 1, but not limited thereto.

In some embodiments, the first electrode 422A of the respective first bonding portion 420A and the first electrode 422B of the respective second bonding portion 420B are, for example, P electrodes, and the second electrode 424A of the respective first bonding portion 420A and the second electrode 424B of the respective second bonding portion 420B are, for example, N electrode. In addition, the first electrode 432 of the backup bonding portion 430 is, for example, a P electrode, and the second electrode 434 of the backup bonding portion 430 is, for example, an N electrode. The P electrode and N electrode here refer to the P-pole and the N-pole corresponding to the light-emitting unit LE. For example, when the light-emitting diode as the light-emitting unit LE is bonded to the first bonding portion 420A to form the sub-pixel 412A, the P-pole contact of the light-emitting diode is bonded to the first electrode 422A, and the N-pole contact of the light-emitting diode is bonded to the second electrode 424A. In some embodiments, the first electrode 422A of respective first bonding portion 420A is closer to the backup bonding portion 430 than the second electrode 424A, and first electrode 422B of respective second bonding portion 420B is closer to the backup bonding portion 430 than the second electrode 424B. Therefore, the polar orientation direction (the relative position of the P-pole and the N-pole) of the light-emitting units LE as the sub-pixels 412A to 412C and the polar orientation direction of the light-emitting units LE as the sub-pixels 414A to 414C can be opposite, but is not limited thereto.

In some embodiments, individual first metal pattern 450A overlap, but do not directly contact, the extension portion 440A. Similarly, individual second metal pattern 450B overlap, but do not directly contact, the extension portion 440B. When patch is required, the corresponding first metal pattern 450A or second metal pattern 450B is electrically connected to the extension portion 440. In some embodiments, individual first metal pattern 450A and extension portion 440A may be in direct contact. Similarly, individual second metal pattern 450B is in direct contact with the extension portion 440B. In this way, the first metal pattern 450A or the second metal pattern 450B corresponding to the sub-pixel that does not need to be patched needs to be disconnected from the extension portion 440 to complete the display device 400.

FIG. 5 is a schematic cross-sectional diagram of a display device of FIG. 4 along a line I-I′ in some embodiments. Referring to FIG. 4 and FIG. 5 simultaneously, in addition to the components described in FIG. 4, the display device 400 also includes a substrate 460 and an insulating layer 470 disposed on the substrate 460. The insulating layer 470 may include organic materials, inorganic materials, or combinations thereof. The insulating layer 470 may have a single-layer structure or a multi-layer structure. In some embodiments, the display device 400 includes multiple metal layers (or circuit layers) disposed on the substrate 460 and multiple insulating layers. For convenience of explanation, only the partial metal layer (or circuit layer) and the insulating layer are shown in FIG. 4. The first metal pattern 450A and the second metal pattern 450B of the display device 400 may be the same metal layer, which is disposed on the first side of the insulating layer 470 close to the substrate 460. The extension portion 440 of the display device 400 and the individual bonding portions (including the first bonding portion 420A, the second bonding portion 420B, and the backup bonding portion 430) may be the same metal layer, which is disposed on the second side of the insulating layer 470 away from the substrate 460. The first side of the insulating layer 470 is opposite to the second side. Therefore, the insulating layer 470 is disposed between the extension portion 440 and at least one of the first metal pattern 450A and the second metal pattern 450B. Since the cross-section of FIG. 4 corresponds to the sub-pixel 412A, FIG. 4 only shows that the insulating layer 470 is disposed between the extension portion 440A and the first metal pattern 450A. However, in a cross-sectional structure (not shown) corresponding to other sub-pixels (e.g., sub-pixel 414A), the insulating layer 470 may be disposed between the extension portion 440B and the second metal pattern 450B. In some embodiments, the first metal pattern 450A and the first electrode 422A of the first bonding portion 420A are different layers, and the display device 400 may further include a conduction pattern 404 penetrating the insulating layer 470 to connect between the first metal pattern 450A and the first electrode 422A. Thus, in FIG. 5, the first metal pattern 450A is electrically connected to the first electrode 422A, but the first metal pattern 450A is electrically disconnected from the extension portion 440.

In addition, the sub-pixel 412A includes a light-emitting unit LE, such as a light-emitting diode, and is bonded to the first electrode 422A and the second electrode 424A of the first bonding portion 420A. In FIG. 4, the display device 400 further includes a protective layer 480, which is disposed on the extension portion 440 and individual bonding portions (including the first bonding portion 420A, the second bonding portion 420B, and the backup bonding portion 430). The protective layer 480 may have multiple bonding openings 482 corresponding to individual bonding portions (including the first bonding portion 420A, the second bonding portion 420B, and the backup bonding portion 430) and a patch opening 484 corresponding to the extension portion 440. The bonding opening 482 may expose first and second electrodes of respective bonding portions (e.g., the first electrode 422A and the second electrode 424A of the first bonding portion 420A and the first electrode 432 and the second electrode 434 of the backup bonding portion 430). The light-emitting unit LE of the sub-pixel 412A can be bonded to the first electrode 422A and the second electrode 424A through the bonding opening 482. In addition, the patch opening 484 corresponding to the extension portion 440 exposes a part of the extension portion 440, where this part overlaps the first metal pattern 450A, for example.

FIG. 6 is a schematic diagram of a display device in FIG. 5 after patch. Please refer to FIG. 5 and FIG. 6 at the same time. When the light-emitting unit LE of the sub-pixel 412A cannot operate normally and needs to be patched, a patch light-emitting unit LE′ can be bonded to the backup bonding portion 430 to form a patch sub-pixel 412D. For example, the patch light-emitting unit LE′ is, for example, a light-emitting diode, and its two contacts are respectively bonded to the first electrode 432 and the second electrode 434 of the backup bonding portion 430 through corresponding bonding opening 482. The patch sub-pixel 412D can produce the same luminous color as the sub-pixel 412A. In addition, the patching step further includes electrically connecting the first electrode 432 of the backup bonding portion 430 to the first electrode 422A of the first bonding portion 422A. In some embodiments, since the first metal pattern 450A is already electrically connected to the first electrode 422A, the extension portion 440A (440) may overlap the first metal pattern 450A. Therefore, the patching step may include performing welding so that the extension portion 440A and the first metal pattern 450A overlapped with each other are connected together. For example, a welding tool WD may be used to perform a welding step at the patch opening 484 to form the conductive pattern 406 penetrating the insulating layer 470. The conductive pattern 406 may be connected between the unwelded part of the extension portion 440A and the first metal pattern 450A, so that the conductive pattern 404, the first metal pattern 450A, the conductive pattern 406, and the extension portion 440A may establish a continuous conductor path between the first electrode 422A of the first bonding portion 420A and the first electrode 432 of the backup bonding portion 430. Therefore, the first electrode 432 of the backup bonding portion 430 can receive the signal of the first electrode 422A of the first bonding portion 420A, so that the patch sub-pixel 412D can exhibit the brightness intended to be emitted by the sub-pixel 412A to realize the complete function of the display device 400.

FIG. 6 only illustrates the patch method and the patched structure of the display device 400 by using the sub-pixel 412A that needs to be patched. However, the structure presented in FIG. 6 can be applied to all sub-pixels (412A to 412C and 414A to 414C) in the display device 400. If all sub-pixels (412A to 412C and 414A to 414C) do not need to be patched, the extension portion 440 can overlap both the first metal pattern 450A and the second metal pattern 450B, but are not electrically connected to each other. In the case of patch, the extension portion 450 may overlap one of the first metal pattern 450A and the second metal pattern 450B and be connected to the other of the first metal pattern 450A and the second metal pattern 450B.

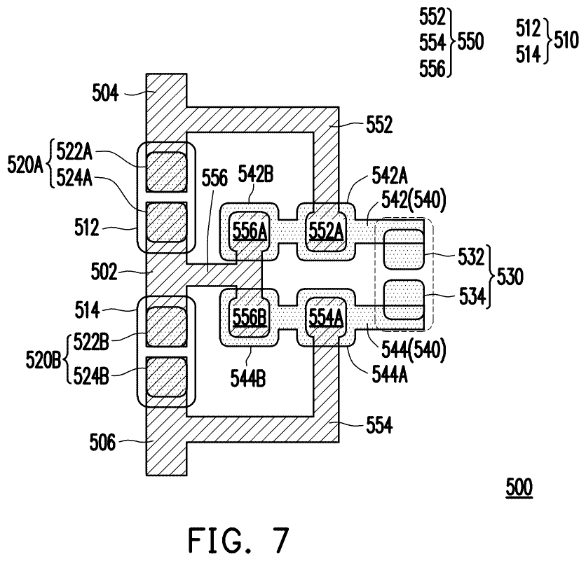

FIG. 7 is a schematic diagram of a partial component layout of a display device according to some embodiments of the disclosure. A display device 500 includes multiple sub-pixels 510 and FIG. 7 schematically shows a single sub-pixel 510 for illustration. Compared with FIG. 1, the number of light-emitting units in the sub-pixel 510 (for example, the first sub-pixel) may be multiple (for example, two light-emitting units), and the number of bonding portions of the same sub-pixel may be multiple (for example, two first bonding portions). The sub-pixel 510 includes a light-emitting unit 512 and a light-emitting unit 514, and the display device 500 includes a light-emitting unit bonding portion 520A (or the first bonding portion) and a light-emitting unit bonding portion 520B (or the first bonding portion). The light-emitting unit 512 may correspond to the light-emitting unit bonding portion 520A, and the light-emitting unit 514 may correspond to the light-emitting unit bonding portion 520B. In some embodiments, the same driving signal may be provided to the light-emitting unit 512 of the sub-pixel 510 and the light-emitting unit 514 of the sub-pixel 510. In some embodiments, the light-emitting unit 512 of the sub-pixel 510 and the light-emitting unit 514 of the sub-pixel 510 may be connected in series and controlled by the same sub-pixel circuit (e.g., sub-pixel switch/sub-pixel transistor). In some embodiments, a single sub-pixel 510 may be composed of J light-emitting units electrically connected in series and controlled by the same switching element (e.g., a transistor), where J may be greater than or equal to 2. In addition, the display device 500 further includes a backup bonding portion 530, and the backup bonding portion 530 can provide one of the light-emitting unit 512 and the light-emitting unit 514 for patch. Therefore, the backup bonding portion 530 can provide patch for different light-emitting units of the same sub-pixel.

In this embodiment, the light-emitting unit 512 and the light-emitting unit 514 include, for example, light-emitting diodes and are used to emit light of the same color. The light-emitting unit bonding portion 520A includes a first electrode 522A and a second electrode 524A, and the light-emitting unit bonding portion 520B includes a first electrode 522B and a second electrode 524B. The first electrode 522A and the first electrode 522B may be electrodes of the same polarity, such as P electrodes, and the second electrode 524A and the second electrode 524B may be electrodes of the same polarity, such as N electrodes. In this embodiment, the second electrode 524A of the light-emitting unit bonding portion 520A and the first electrode 522B of the light-emitting unit bonding portion 520B may be connected to each other, for example, through a connection pattern 502. In addition, the first electrode 522A of the light-emitting unit bonding portion 520A is connected to a connection pattern 504, and the second electrode 524B of the light-emitting unit bonding portion 520B is connected to a connection pattern 506. In some embodiments, one of the connection pattern 504 and the connection pattern 506 may be connected to a N-pole signal and the other may be connected to a P-pole signal. In some embodiments, one of the connection pattern 504 and the connection pattern 506 may be connected to the ground potential and the other may be connected to a switching element (transistor, not shown) in the sub-pixel circuit. In some embodiments, the light-emitting unit 512 and the light-emitting unit 514 are connected in series and controlled by the same switching element.

The display device 500 also includes an extension portion 540, and the extension portion 540 may include a first electrode extension portion 542 and a second electrode extension portion 544. The first electrode extension portion 542 can be electrically connected to a first electrode 532 of the backup bonding portion 530, and the second electrode extension portion 544 can be electrically connected to a second electrode 534 of the backup bonding portion 530. The display device 500 also includes a metal pattern 550, and the metal pattern 550 may include a first electrode metal pattern 552, a second electrode metal pattern 554, and a series metal pattern 556. The first electrode metal pattern 552 may be electrically connected to the first electrode 522A of the light-emitting unit bonding portion 520A and overlap with the first electrode extension portion 542. The second electrode metal pattern 554 may be electrically connected to the second electrode 524B of the light-emitting unit bonding portion 520B and overlap with the second electrode extension portion 544. The series metal pattern 556 can electrically connect the second electrode 524A of the light-emitting unit bonding portion 520A and the first electrode 522B of the light-emitting unit bonding portion 520B, and overlap with the first electrode extension portion 542 and the second electrode extension portion 544 at the same time.

In this embodiment, the first electrode extension portion 542 may include a patch region 542A and a patch region 542B. The patch region 552A of the first electrode metal pattern 552 overlaps the patch region 542A, and the patch region 556A of the series metal pattern 556 overlaps the patch region 542B. The second electrode extension portion 544 may include a patch region 544A and a patch region 544B. The patch region 554A of the second electrode metal pattern 554 overlaps the patch region 544A, and the patch region 556B of the series metal pattern 556 overlaps the patch region 544B.

When the light-emitting unit 512 in the sub-pixel 510 needs to be patched, in addition to bonding the light-emitting unit used for patching to the backup bonding portion 530, the first electrode 532 of the backup bonding portion 530 needs to be electrically connected to the first electrode 522A of the light-emitting unit bonding portion 520A, and the second electrode 534 of the backup bonding portion 530 needs to be electrically connected to the second electrode 524A of the light-emitting unit bonding portion 520A. Therefore, the patch method of the display device 500 may include electrically connecting the patch region 542A to the patch region 552A and electrically connecting the patch region 544B to the patch region 556B. In this way, the first electrode 532 of the backup bonding portion 530 can be electrically connected to the first electrode 522A of the light-emitting unit bonding portion 520A through the first electrode extension portion 542, the connection structure of the patch region 542A and the patch region 552A, the first electrode metal pattern 552, and the connection pattern 504. At the same time, the second electrode 534 of the backup bonding portion 530 can be electrically connected to the second electrode 524A of the light-emitting unit bonding portion 520A through the second electrode extension portion 544, the connection structure of the patch region 544B and the patch region 556B, the series metal pattern 556, and the connection pattern 502.

When the light-emitting unit 514 in the sub-pixel 510 needs to be patched, in addition to bonding the patch sub-pixel to the backup bonding portion 530, the first electrode 532 of the backup bonding portion 530 needs to be electrically connected to the first electrode 522B of the light-emitting unit bonding portion 520B, and the second electrode 534 of the backup bonding portion 530 needs to be electrically connected to the second electrode 524B of the light-emitting unit bonding portion 520B. Therefore, the patch method of the display device 500 may include electrically connecting the patch region 542B to the patch region 556A and electrically connecting the patch region 544A to the patch region 554A. In this way, the first electrode 532 of the backup bonding portion 530 can be electrically connected to the first electrode 522B of the light-emitting unit bonding portion 520B through the first electrode extension portion 542, the connection structure of the patch region 542B and the patch region 556A, the series metal pattern 556, and the connection pattern 502. At the same time, the second electrode 534 of the backup bonding portion 530 can be electrically connected to the second electrode 524B of the light-emitting unit bonding portion 520B through the second electrode extension portion 544, the connection structure of the patch region 544A and the patch region 554A, the second electrode metal pattern 554, and the connection pattern 506.

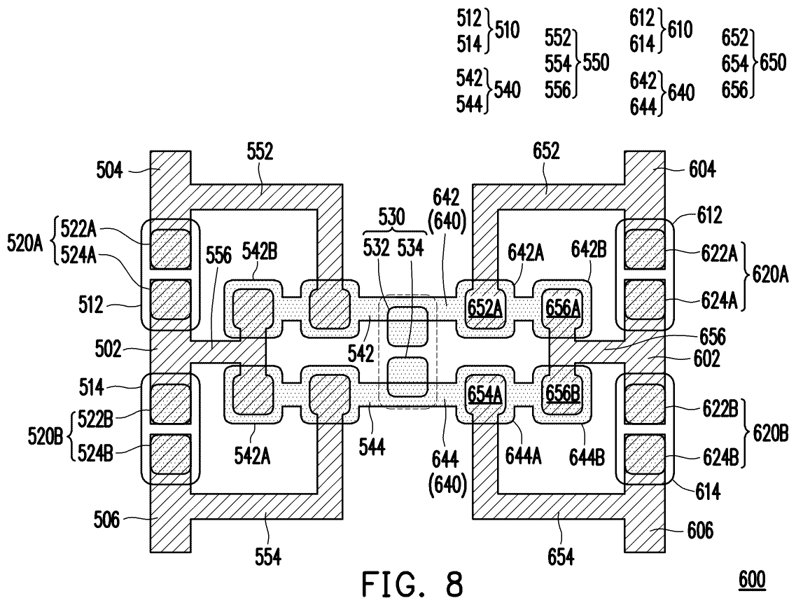

FIG. 8 is a schematic diagram of a partial component layout of a display device according to some embodiments of the disclosure. A display device 600 may be a modified implementation of the display device 500. Therefore, the same reference numerals in the two embodiments shall indicate the same or equivalently replaceable components, and the descriptions of these components may be applied and referenced to each other to understand the embodiments of FIG. 7 and FIG. 8. The display device 600 includes a sub-pixel 610 in addition to the sub-pixel 510 and the backup bonding portion 530, and the sub-pixel 610 includes a light-emitting unit 612 and a light-emitting unit 614. At the same time, the display device 600 also includes a light-emitting unit bonding portion 620A and a light-emitting unit bonding portion 620B. The light-emitting unit 512 of the sub-pixel 510 may correspond to the light-emitting unit bonding portion 520A, and the light-emitting unit 514 of the sub-pixel 510 may correspond to the light-emitting unit bonding portion 520B. The light-emitting unit 612 of the sub-pixel 610 may correspond to the light-emitting unit bonding portion 620A, and the light-emitting unit 614 of the sub-pixel 610 may correspond to the light-emitting unit bonding portion 620B. In addition, the backup bonding portion 530 may provide patch for one of the light-emitting unit 512, the light-emitting unit 514, the light-emitting unit 612, and the light-emitting unit 614. In other words, the backup bonding portion 530 is a patch structure shared by the sub-pixel 510 and the sub-pixel 610.

In some embodiments, the sub-pixel 510 and the sub-pixel 610 may be two sub-pixels in the same pixel. For example, the sub-pixel 510 is the first sub-pixel of A pixel and the sub-pixel 610 the second sub-pixel of the A pixel. The sub-pixel 510 and the sub-pixel 610 can be selectively used to provide different image colors. At this time, the light-emitting unit bonding portion 520A and the light-emitting unit bonding portion 520B in the sub-pixel 510 can be understood as the first bonding portion, and the light-emitting unit bonding portion 620A and the light-emitting unit bonding portion 620B in the sub-pixel 610 can be understood as another first bonding portion, and the individual light-emitting unit bonding portions of the two sets of first bonding portions may be connected to the backup bonding portion 530 to achieve patch if necessary. In some embodiments, the sub-pixel 510 and the sub-pixel 610 may be two sub-pixels in different pixels. For example, the sub-pixel 510 is the first sub-pixel of A pixel and the sub-pixel 610 is the second sub-pixel of B pixel. The sub-pixel 510 and the sub-pixel 610 can be selectively used to provide the same or different image colors. At this time, the light-emitting unit bonding portion 520A and the light-emitting unit bonding portion 520B in the sub-pixel 510 can be understood as the first bonding portion, and the light-emitting unit bonding portion 620A and the light-emitting unit bonding portion 620B in the sub-pixel 610 can be understood as the second bonding portion, and the individual light-emitting unit bonding portions of the first bonding portion and the second bonding portion may be connected to the backup bonding portion 530 to achieve patch if necessary. In other words, the backup bonding portion 530 can be used as a patch structure within the same pixel or as a patch structure shared by different pixels.

In this embodiment, the light-emitting units 512, 514, 612, and 614 include, for example, light-emitting diodes to provide display light. The light-emitting unit bonding portion 520A (the first electrode 522A and the second electrode 524A), the light-emitting unit bonding portion 520B (the first electrode 522B and the second electrode 524B), the connection patterns 502 to 506, and the metal pattern 550 (the first electrode metal pattern 552, the second electrode metal pattern 554, and the series metal pattern 556), the backup bonding portion 530 (the first electrode 532 and the second electrode 534) and other components) have been described in FIG. 5, and therefore will not be repeated in the following.

The light-emitting unit bonding portion 620A includes a first electrode 622A and a second electrode 624A, and the light-emitting unit bonding portion 620B includes a first electrode 622B and a second electrode 624B. The first electrode 622A and the first electrode 622B may be electrodes of the same polarity, such as P electrodes, and the second electrode 624A and the second electrode 624B may be electrodes of the same polarity, such as N electrodes. In this embodiment, the second electrode 624A of the light-emitting unit bonding portion 620A and the first electrode 622B of the light-emitting unit bonding portion 620B may be connected to each other, for example, through a connection pattern 602. The first electrode 622A of the light-emitting unit bonding portion 620A is connected to a connection pattern 604, and the second electrode 624B of the light-emitting unit bonding portion 620B is connected to a connection pattern 606. In some embodiments, one of the connection pattern 604 and the connection pattern 606 may be connected to the N-pole signal and the other may be connected to the P-pole signal. In some embodiments, one of the connection pattern 604 and the connection pattern 606 may be connected to the ground potential and the other may be connected to a switching element (transistor) in the sub-pixel circuit. In some embodiments, the light-emitting unit 612 and the light-emitting unit 614 are connected in series and controlled by the same switching element. In some embodiments, the sub-pixel 510 and the sub-pixel 610 are controlled by different switching elements. For example, the sub-pixel 510 is electrically connected to and controlled by the first switching element, and sub-pixel 610 is electrically connected to and controlled by the second switching element. The display device 600 also includes an extension portion 640, and the extension portion 640 may include a first electrode extension portion 642 and a second electrode extension portion 644. In some embodiments, the first electrode extension portion 642 of the extension portion 640 and the first electrode extension portion 542 of the extension portion 540 may be continuously and integrally connected to the first electrode 532 of the backup bonding portion 530, and the second electrode extension portion 644 of the extension portion 640 and the second electrode extension portion 544 of the extension portion 540 may be continuously and integrally connected to the second electrode 534 of the backup bonding portion 530, but is not limited thereto. Therefore, the first electrode extension portion 642 can be electrically connected to the first electrode 532 of the backup bonding portion 530, and the second electrode extension portion 644 can be electrically connected to the second electrode 534 of the backup bonding portion 530.

The display device 600 also includes a metal pattern 650, and the metal pattern 650 may include a first electrode metal pattern 652, a second electrode metal pattern 654, and a series metal pattern 656. The first electrode metal pattern 652 may be electrically connected to the first electrode 622A of the light-emitting unit bonding portion 620A and overlap with the first electrode extension portion 642. The second electrode metal pattern 654 may be electrically connected to the second electrode 624B of the light-emitting unit bonding portion 620B and overlap with the second electrode extension portion 644. The series metal pattern 656 can electrically connect the second electrode 624A of the light-emitting unit bonding portion 620A and the first electrode 622B of the light-emitting unit bonding portion 620B, and overlap with the first electrode extension portion 642 and the second electrode extension portion 644 at the same time. In some embodiments, the sub-pixel 510 and the sub-pixel 610 may belong to different pixels. In this way, the light-emitting unit bonding portion 520A and the light-emitting unit bonding portion 520B can be understood as the first bonding portion, the light-emitting unit bonding portion 620A and the light-emitting unit bonding portion 620B can be understood as the second bonding portion, and the metal pattern 550 and the metal pattern 650 can be regarded as respectively first metal pattern and second metal pattern. The first bonding portion (the light-emitting unit bonding portion 520A and the light-emitting unit bonding portion 520B) is electrically connected to the first metal pattern (the metal pattern 550), and the second bonding portion (the light-emitting unit bonding portion 620A and the light-emitting unit bonding portion 620B) is electrically connected to the second metal pattern (the metal pattern 650), and the extension portion 640 overlaps with at least one of the first metal pattern (the metal pattern 550) and the second metal pattern (the metal pattern 650). In some embodiments, the metal pattern 550 and the metal pattern 650 may be made of the same metal layer, but are not limited thereto. In some embodiments, the extension portion 540, the extension portion 640, the first electrode 532 of the backup bonding portion 530, and the second electrode 534 of the backup bonding portion 530 may be made of the same metal layer, but are not limited thereto. The first electrode extension portion 542, the first electrode extension portion 532 of the backup bonding portion 530, and the first electrode extension portion 642 may be formed of an integral continuous conductive pattern. The second electrode extension portion 544, the second electrode extension portion 534 of the backup bonding portion 530, and the second electrode extension portion 644 may be composed of an integral continuous conductive pattern. In this embodiment, the first electrode extension portion 642 may include a patch region 642A and a patch region 642B. A patch region 652A of the first electrode metal pattern 652 overlaps the patch region 642A, and a patch region 656A of the series metal pattern 656 overlaps the patch region 642B. The second electrode extension portion 644 may include a patch region 644A and a patch region 644B, where a patch region 654A of the second electrode metal pattern 654 overlaps the patch region 644A and a patch region 656B of the series metal pattern 656 overlaps the patch region 644B.

The patch method of the light-emitting unit 512 and the light-emitting unit 514 can be implemented when the light-emitting unit 612 and the light-emitting unit 614 need to be patched. Therefore, the backup bonding portion 530 may be used for patching one of the light-emitting unit 512, the light-emitting unit 514, the light-emitting unit 612, and the light-emitting unit 614. In the display device 600, each sub-pixel 510/610 has two light-emitting units connected in series, and the sub-pixel 510 and the sub-pixel 610 can share a patch structure (the backup bonding portion 530). In this way, the number of the patch structure (the backup bonding portion 530) can be ¼ the number of the light-emitting unit of the sub-pixel, thereby reserving more installation area for the sub-pixel to achieve a high display aperture ratio.

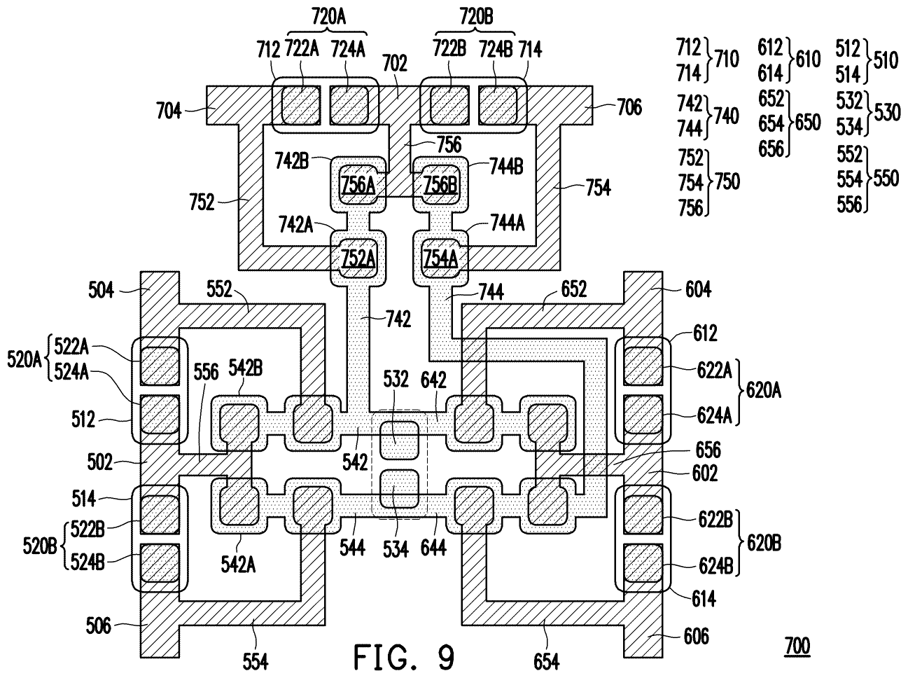

FIG. 9 is a schematic diagram of a partial component layout of a display device according to some embodiments of the disclosure. A display device 700 may be a modified implementation of the display device 600. Therefore, the same reference numerals in the two embodiments shall indicate the same or equivalently replaceable components, and the descriptions of the components may be applied and referenced to each other to understand embodiments of FIG. 7 and FIG. 8. The display device 700 includes a sub-pixel 510, a backup bonding portion 530, and a sub-pixel 610, and also includes a sub-pixel 710. The sub-pixel 710 may include a light-emitting unit 712 and a light-emitting unit 714. At the same time, the display device 700 also includes a light-emitting unit bonding portion 720A and a light-emitting unit bonding portion 720B. The light-emitting unit 512 of the sub-pixel 510 may correspond to the light-emitting unit bonding portion 520A, and the light-emitting unit 514 of the sub-pixel 510 may correspond to the light-emitting unit bonding portion 520B. The light-emitting unit 612 of the sub-pixel 610 may correspond to the light-emitting unit bonding portion 620A, and the light-emitting unit 614 of the sub-pixel 610 may correspond to the light-emitting unit bonding portion 620B. The light-emitting unit 712 of the sub-pixel 710 may correspond to the first bonding portion 720A, and the light-emitting unit 714 of the sub-pixel 710 may correspond to the second bonding portion 720B. In addition, the backup bonding portion 530 may provide patch for one of the light-emitting unit 512, the light-emitting unit 514, the light-emitting unit 612, the light-emitting unit 614, the light-emitting unit 712, and the light-emitting unit 714. In other words, the backup bonding portion 530 is a patch structure shared by the sub-pixel 510, the sub-pixel 610, and the sub-pixel 710.

In some embodiments, the sub-pixel 510, the sub-pixel 610, and the sub-pixel 710 may be three sub-pixels in the same pixel. For example, the sub-pixel 510 is the first sub-pixel of A pixel, the sub-pixel 610 is the second sub-pixel of A pixel, and the sub-pixel 710 is the third sub-pixel of A pixel. The sub-pixel 510, the sub-pixel 610, and the sub-pixel 710 can be selectively used to provide different image colors, but are not limited thereto. At this time, the light-emitting unit bonding portion 520A and the light-emitting unit bonding portion 520B in the sub-pixel 510 can be understood as the first bonding portion, and the light-emitting unit bonding portion 620A the light-emitting unit bonding portion 620B in the sub-pixel 610 can be understood as another first bonding portion, and the light-emitting unit bonding portion 720A and the light-emitting unit bonding portion 720B in the sub-pixel 710 can be understood as another first bonding portion. The individual light-emitting unit bonding portion of the three sets of the first bonding portions may be connected to the backup bonding portion 530 as needed to implement patching. In some embodiments, two of the sub-pixels 510, 610, and 710 are two sub-pixels in the same pixel, and one of the sub-pixels is sub-pixel in another pixel. For example, the sub-pixel 510 is the first sub-pixel of A pixel, the sub-pixel 610 is the second sub-pixel of A pixel, and the sub-pixel 710 is the third sub-pixel of B pixel. The sub-pixel 510, the sub-pixel 610, and the sub-pixel 710 can be selectively used to provide the same or different image colors. In some embodiments, the sub-pixel 510, the sub-pixel 610, and the sub-pixel 710 may be three sub-pixels in different pixels. For example, the sub-pixel 510 is the first sub-pixel of A pixel, the sub-pixel 610 is the second sub-pixel of B pixel, and the sub-pixel 710 is the third sub-pixel of C pixel. The sub-pixel 510, the sub-pixel 610, and the sub-pixel 710 can be selectively used to provide the same or different image colors. At this time, the light-emitting unit bonding portion 520A and the light-emitting unit bonding portion 520B in the sub-pixel 510 can be understood as the first bonding portion, the light-emitting unit bonding portion 620A and the light-emitting unit bonding portion 620B in the sub-pixel 610 can be understood as the second bonding portion, and the light-emitting unit bonding portion 720A and the light-emitting unit bonding portion 720B in the sub-pixel 710 can be understood as the third bonding portion. The individual light-emitting unit bonding portion of the first bonding portion, the second bonding portion, and the third bonding portion can be connected to the backup bonding portion 530 as needed to implement patching. In other words, the backup bonding portion 530 can be used as a patch structure within the same pixel or as a patch structure shared by different pixels.

In this embodiment, the light-emitting units 512, 514, 612, 614, 712, and 714 are, for example, light-emitting diodes. The light-emitting unit bonding portion 520A (the first electrode 522A and the second electrode 524A), the light-emitting unit bonding portion 520B (the first electrode 522B and the second electrode 524B), the connection patterns 502 to 506, the metal pattern 550 (the first electrode metal pattern 552, the second electrode metal pattern 554, and the series metal pattern 556), the backup bonding portion 530 (the first electrode 532 and the second electrode 534), the light-emitting unit bonding portion 620A (the first electrode 622A and the second electrode 624A), the light-emitting unit bonding portion 620B (the first electrode 622B and the second electrode 624B), the connection patterns 602 to 606, the metal pattern 650 (the first electrode metal pattern 652, the second electrode metal pattern 654, and the series metal pattern 656) and other components have been described in FIG. 5 and FIG. 6, and therefore will not be repeated in the following.

The first bonding portion 720A includes a first electrode 722A and a second electrode 724A, and second bonding portion 720B includes a first electrode 722B and a second electrode 724B. The first electrode 722A and the first electrode 722B may be electrodes of the same polarity, such as P electrodes, and the second electrode 724A and the second electrode 724B may be electrodes of the same polarity, such as N electrodes. In this embodiment, the second electrode 724A of the first bonding portion 720A and the first electrode 722B of the second bonding portion 720B may be connected to each other, for example, through a connection pattern 702. The first electrode 722A of the first bonding portion 720A is connected to a connection pattern 704, and the second electrode 724B of the second bonding portion 720B is connected to a connection pattern 706. The connection pattern 704 and the connection pattern 706 may be connected to other sub-pixels or circuits not shown. In some embodiments, one of the connection pattern 704 and the connection pattern 706 may be connected to the N-pole signal and the other may be connected to the P-pole signal. In some embodiments, one of the connection pattern 704 and the connection pattern 706 may be connected to a ground potential and the other may be connected to a switching element (transistor) in a sub-pixel circuit. In some embodiments, the light-emitting unit 712 and the light-emitting unit 714 are connected in series and controlled by the same switching element. In some embodiments, the sub-pixel 510, the sub-pixel 610, and the sub-pixel 710 are controlled by different switching elements. For example, the sub-pixel 510 is electrically connected to and controlled by the first switching element, the sub-pixel 610 is electrically connected to and controlled by the second switching element, and the sub-pixel 710 is electrically connected to and controlled by the third switching element.

The display device 700 also includes an extension portion 740, and the extension portion 740 may include a first electrode extension portion 742 and a second electrode extension portion 744. The first electrode extension portion 742, the first electrode extension portion 642, and the first electrode extension portion 542 are electrically connected, and the second electrode extension portion 744, the second electrode extension portion 644, and the second electrode extension portion 544 are electrically connected. In some embodiments, the first electrode extension portion 742 can be electrically connected to first electrode 532 of the backup bonding portion 530 and the second electrode extension portion 744 can be electrically connected to the second electrode 534 of the backup bonding portion 530. The display device 700 also includes a metal pattern 750, and the metal pattern 750 may include a first electrode metal pattern 752, a second electrode metal pattern 754, and a series metal pattern 756. The first electrode metal pattern 752 may be electrically connected to the first electrode 722A of the first bonding portion 720A and overlap the first electrode extension portion 742. The second electrode metal pattern 754 may be electrically connected to the second electrode 724B of the second bonding portion 720B and overlap the second electrode extension portion 744. The series metal pattern 756 may electrically connect the second electrode 724A of the first bonding portion 720A and the first electrode 722B of the second bonding portion 720B while overlapping the first electrode extension portion 742 and the second electrode extension portion 744.

In this embodiment, the first electrode extension portion 742 may include a patch region 742A and a patch region 742B. A patch region 752A of the first electrode metal pattern 752 overlaps the patch region 742A, and a patch region 756A of the series metal pattern 756 overlaps the patch region 742B. The second electrode extension portion 744 may include a patch region 744A and a patch region 744B. A patch region 754A of the second electrode metal pattern 754 overlaps the patch region 744A, and a patch region 756B of the series metal pattern 756 overlaps the patch region 744B.

The patch method of the light-emitting unit 512 and the light-emitting unit 514 can be implemented when the light-emitting unit 712 and the light-emitting unit 714 need to be patched. Therefore, the backup bonding portion 530 may be used for patching one of the light-emitting unit 512, the light-emitting unit 514, the light-emitting unit 612, the light-emitting unit 614, the light-emitting unit 712, and the light-emitting unit 714. In the display device 700, each sub-pixel 510/610/710 has two light-emitting units connected in series, and the sub-pixel 510, the sub-pixel 610, and the sub-pixel 710 can share a patch structure (the backup bonding portion 530). In this way, the ration of the number of the patch structure (the backup bonding portion 530) to the number of the light-emitting unit of the sub-pixel can be 1 to 6, thereby reserving more installation area for the sub-pixel to achieve a high display aperture ratio

In summary, the display device in the embodiment of the disclosure provides a backup bonding portion shared by multiple sub-pixels for patch. A metal pattern and an extension portion are disposed between the bonding portion and the backup bonding portion of individual sub-pixels. Patch can be achieved by bonding the light-emitting unit to the backup bonding portion, and connecting the metal pattern and the extension portion in a required manner or maintaining electrical disconnection from each other. Therefore, the display device has ideal manufacturing yield. In addition, the backup bonding portion can be shared by multiple sub-pixels, and the layout area of the sub-pixel does not need to be sacrificed due to the setting of the backup bonding portion. This allows the sub-pixels to be arranged in a denser manner to achieve high resolution, high pixel density, high brightness and other requirements.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device, comprising:
a first pixel, the first pixel comprising a first sub-pixel and a second sub-pixel, and the first sub-pixel and the second sub-pixel being disposed corresponding to two first bonding portions, wherein each of the two first bonding portions comprises a first electrode and a second electrode;
a second pixel, the second pixel comprising a third sub-pixel and a fourth sub-pixel, and the third sub-pixel and the fourth sub-pixel being disposed corresponding to two second bonding portions, wherein each of the two second bonding portions comprises a first electrode and a second electrode;
at least one backup bonding portion, being adjacent to the first pixel and the second pixel and electrically connected to an extension portion, wherein the at least one backup bonding portion comprises a first electrode and a second electrode;
wherein the first electrode of one of the two first bonding portions is electrically connected to a first metal pattern, the first electrode of one of the two second bonding portions is electrically connected to a second metal pattern, and the extension portion is disposed on the first metal pattern and the second metal pattern and overlaps at least one of the first metal pattern and the second metal pattern.

2. The display device according to claim 1 further comprising an insulating layer, disposed between the extension portion and the at least one of the first metal pattern and the second metal pattern.

3. The display device according to claim 1, wherein a color of the first sub-pixel is different from a color of the second sub-pixel.

4. The display device according to claim 1, wherein the first sub-pixel and the second sub-pixel are controlled by a first switching element and a second switching element respectively.

5. The display device according to claim 1, wherein the first electrode of the at least one backup bonding portion is connected to the extension portion.

6. The display device according to claim 5, wherein the first electrode of the at least one backup bonding portion and the extension portion are an integral continuous conductive pattern.

7. The display device according to claim 1, wherein the extension portion comprises a first electrode extension portion and a second electrode extension portion, the first electrode of the at least one backup bonding portion is connected to the first electrode extension portion, and the second electrode of the at least one backup bonding portion is connected to the second electrode extension portion.

8. The display device according to claim 1, wherein the second electrode of each of the two first bonding portions, the two second bonding portions, and the at least one backup bonding portion is connected to a same potential.

9. The display device according to claim 1, wherein the extension portion overlaps one of the first metal pattern and the second metal pattern, and the extension portion is connected to one of the first metal pattern and the second metal pattern.

10. The display device according to claim 1, wherein the extension portion overlaps both the first metal pattern and the second metal pattern.

11. The display device according to claim 1, wherein each of the first sub-pixel and the second sub-pixel comprises at least one light-emitting unit, and the at least one light-emitting unit is bonded to the first electrode and the second electrode of the each of the two first bonding portions.

12. The display device according to claim 11, wherein the each of the first sub-pixel and the second sub-pixel comprises a plurality of light-emitting units, and the light-emitting units are connected in series.

13. The display device according to claim 1, wherein each of the third sub-pixel and the fourth sub-pixel comprises at least one light-emitting unit, and the at least one light-emitting unit is bonded to the first electrode and the second electrode of the each of the two second bonding portions.

14. The display device according to claim 13, wherein the each of the third sub-pixel and the fourth sub-pixel comprises a plurality of light-emitting units, and the light-emitting units are connected in series.

15. The display device according to claim 1, further comprising a patch light-emitting unit bonded to the first electrode and the second electrode of the at least one backup bonding portion.

16. The display device according to claim 1, wherein the second electrode of each of the two first bonding portions, the two second bonding portions, and the at least one backup bonding portion is connected together through an electrode connection pattern.

17. The display device according to claim 1, wherein the first electrode of one of the two first bonding portions and the first metal pattern are in different layers.

18. The display device according to claim 1, wherein the first electrode of one of the two first bonding portions is connected to the first metal pattern through a conductive pattern.

19. The display device according to claim 1, wherein the extension portion is welded to the at least one of the first metal pattern and the second metal pattern.

20. The display device according to claim 1, wherein the first electrode of an other one of the two first bonding portions is electrically connected to an other first metal pattern, and the first electrode of an other one of the two second bonding portions is electrically connected to an other second metal pattern.
